(19) United States
(12) Patent Application Publication
(10) Pub. No.: US 2021/0166910 A1
(43) Pub. Date: Jun. 3, 2021

(54) SUBSTRATE SUPPORT PLATE, SUBSTRATE PROCESSING APPARATUS INCLUDING THE SAME, AND SUBSTRATE PROCESSING METHOD

(71) Applicant: ASM IP Holding B.V., Almere (NL)

(72) Inventors: DaeYoun Kim, Seo-gu (KR); JaeHyun Kim, Hwaseong-si (KR); SeungHwan Lee, Anseong-si (KR)

(21) Appl. No.: 17/103,904

(22) Filed: Nov. 24, 2020

Related U.S. Application Data
(60) Provisional application No. 62/942,617, filed on Dec. 2, 2019.

(51) Int. Cl. H01J 37/20; H01J 37/32; H01L 21/311

(52) U.S. Cl. CPC H01J 37/20; H01L 21/31122; H01J 37/3244

(57) ABSTRACT

A substrate processing apparatus capable of selective processing a thin film in a bevel region thereof includes a substrate support plate for supporting a substrate to be processed, the substrate support plate including: an inner portion having an upper surface having an area less than that of the substrate to be processed; and a peripheral portion surrounding the inner portion, wherein an upper surface of the peripheral portion is below the upper surface of the inner portion.

### CROSS-REFERENCE TO RELATED APPLICATION

This application is based on and claims priority under 35 U.S.C. § 119 to U.S. Patent Application No. 62/942,617 filed on Dec. 2, 2019, in the United States Patent and Trademark Office, the disclosure of which is incorporated by reference herein in its entirety.

### BACKGROUND

### 1. Field

One or more embodiments relate to a substrate support plate, and more particularly, to a substrate support plate, a substrate processing apparatus including the substrate support plate, and a substrate processing method using the substrate support plate.

### 2. Description of Related Art

When a thin film is formed on a substrate, portions of the thin film deposited on upper and lower edges of the substrate may be peeled off in a subsequent process. Therefore, the film deposited on the upper and lower edges of the substrate may act as a contaminant forming, for example, particles in a reaction space, which may cause an increase of a device failure rate.

FIG. 1 shows a thin film deposited on the edge of a substrate. Referring to FIG. 1, a thin film 94 is deposited on a portion of an upper surface 92, a side surface 95, and a rear surface 93 of a substrate 91. In particular, films a and b deposited on a portion of the side surface 95 and the rear surface 93 of the substrate are peeled off in a subsequent process, thereby causing contamination of a reactor and a structure on the substrate.

### SUMMARY

One or more embodiments include selective processing of thin films deposited on an edge of a substrate (e.g., bevel region). In more detail, one or more embodiments include a substrate processing apparatus and a substrate processing method capable of removing a thin film deposited on an edge of a substrate.

One or more embodiments include selective removal of thin films on substrate edges, such as bevel edge regions. In addition, one or more embodiments include ensuring the symmetry of a bevel etching width on a substrate, through control of process parameters (e.g., supply conditions for RF power and/or flow rate control of an incoming gas), regardless of a alignment position of the substrate on a substrate support plate such as a susceptor.

Additional aspects will be set forth in part in the description which follows and, in part, will be apparent from the description, or may be learned by practice of the presented embodiments of the disclosure.

According to one or more embodiments, a substrate support plate for supporting a substrate to be processed, includes: an inner portion having an upper surface having an area less than that of the substrate to be processed; and a peripheral portion surrounding the inner portion, wherein an upper surface of the peripheral portion is below the upper surface of the inner portion, and the peripheral portion may include at least one path.

According to an example of the substrate support plate, the substrate support plate may further include at least one pad disposed on the inner portion.

According to another example of the substrate support plate, the path may extend from a portion of the peripheral portion to another portion of the peripheral portion.

According to another example of the substrate support plate, the path may include: a first portion extending from a side surface of the substrate support plate toward the peripheral portion; and a second portion extending from the peripheral portion toward an upper surface of the substrate support plate.

According to another example of the substrate support plate, the path may include a plurality of paths, and the plurality of paths may be symmetrically formed with respect to the center of the substrate support plate.

According to another example of the substrate support plate, the inner portion may include a through hole having a diameter different from that of the path.

According to another example of the substrate support plate, the distance from the center of the substrate support plate to the path may be less than the radius of the substrate to be processed.

According to one or more embodiments, a substrate processing apparatus includes: a substrate support plate including an inner portion having an upper surface of an area less than that of a substrate to be processed and a peripheral portion surrounding the inner portion, wherein an upper surface of the peripheral portion is below an upper surface of the inner portion; and a gas supply unit on the substrate support plate, wherein a first distance between the inner portion and the gas supply unit may be less than a second distance between the peripheral portion and the gas supply unit.

According to an example of the substrate processing apparatus, when the substrate to be processed is mounted on the inner portion, a distance between the substrate to be processed and the gas supply unit may be about 1 mm or less, and the second distance between the peripheral portion and the gas supply unit may be about 3 mm or more.

According to another example of the substrate processing apparatus, the inner portion may form a convex portion of the substrate support plate, and the peripheral portion may form a concave portion of the substrate support plate.

According to another example of the substrate processing apparatus, the gas supply unit may include a plurality of injection holes, and the plurality of injection holes may be distributed over an area less than the area of the substrate to be processed.

According to another example of the substrate processing apparatus, the plurality of injection holes may be distributed over an area less than the area of the upper surface of the inner portion.

According to another example of the substrate processing apparatus, the gas supply unit includes a plurality of injection holes, and a first lower surface of the gas supply unit in a region where the plurality of injection holes are distributed may be flush with a second lower surface of the gas supply unit outside the region where the plurality of injection holes are distributed.

According to another example of the substrate processing apparatus, a distance between the upper surface of the substrate to be processed and the first lower surface of the gas supply unit and a distance between the upper surface of the substrate to be processed and the second lower surface of the gas supply unit are constant, and accordingly, the processing of a thin film on an edge region of the substrate to be processed disposed between the peripheral portion and the gas supply unit may be performed without a separate alignment operation.

According to another example of the substrate processing apparatus, a reaction space may be formed between the substrate support plate and the gas supply unit, and the reaction space may include a first reaction space between the inner portion and the gas supply unit; and a second reaction space between the peripheral portion and the gas supply unit.

According to another example of the substrate processing apparatus, power may be supplied between the gas supply unit and the substrate support plate to generate plasma, and less plasma is generated in the first reaction space than in the second reaction space.

According to another example of the substrate processing apparatus, the peripheral portion may include at least one path.

According to another example of the substrate processing apparatus, the substrate processing apparatus may be configured to supply, through the path, a gas reactive with a thin film on the substrate to be processed.

According to another example of the substrate processing apparatus, the substrate processing apparatus may be configured to supply, through the gas supply unit, a gas different from the gas reactive with the thin film.

According to one or more embodiments, a substrate processing method includes: mounting a substrate to be processed on the substrate support plate described above; generating plasma by supplying power between a gas supply unit on the substrate support plate and the substrate support plate; and removing at least a portion of a thin film on an edge region of the substrate to be processed using the plasma, wherein during the generating of the plasma, less plasma is generated in a first space between the inner portion and the gas supply unit than in a second space between the peripheral portion and the gas supply unit.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 shows a thin film deposited on the edge of a substrate;

FIG. 2 is a view of a substrate support plate according to an embodiment of the inventive concept;

FIGS. 3 to 6 are views of a substrate processing apparatus according to embodiments of the inventive concept;

FIGS. 7 and 8 are views of a substrate support plate according to embodiments of the inventive concept;

FIGS. 9 and 10 are views of a substrate processing apparatus according to embodiments of the inventive concept;

FIG. 11 is a view illustrating removal of a carbon thin film through a reaction of an oxygen radical and the carbon thin film;

FIG. 12 is a view of a region where a carbon thin film is removed from an upper edge of a substrate according to an RF power application time;

FIG. 13 is a view illustrating removal of carbon films according to positions;

FIG. 14 is a view illustrating removal of a carbon thin film from a 1 mm edge region of an upper surface of an actual substrate; and

FIG. 15 is a view of a substrate processing apparatus according to embodiments of the inventive concept.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Expressions such as “at least one of,” when preceding a list of elements, modify the entire list of elements and do not modify the individual elements of the list.

The terminology used herein is for the purpose of describing particular embodiments and is not intended to limit the disclosure. As used herein, the singular forms “a”, “an”, and “the” are intended to include the plural forms as well, unless the context clearly indicates otherwise. It will be further understood that the terms “includes”, “comprises” and/or “including”, “comprising” used herein specify the presence of stated features, integers, steps, processes, members, components, and/or groups thereof, but do not preclude the presence or addition of one or more other features, integers, steps, processes, members, components, and/or groups thereof. As used herein, the term “and/or” includes any and all combinations of one or more of the associated listed items.

It will be understood that, although the terms first, second, etc. may be used herein to describe various members, components, regions, layers, and/or sections, these members, components, regions, layers, and/or sections should not be limited by these terms. These terms do not denote any order, quantity, or importance, but rather are only used to distinguish one component, region, layer, and/or section from another component, region, layer, and/or section. Thus, a first member, component, region, layer, or section discussed below could be termed a second member, component, region, layer, or section without departing from the teachings of embodiments.

Embodiments of the disclosure will be described hereinafter with reference to the drawings in which embodiments of the disclosure are schematically illustrated. In the drawings, variations from the illustrated shapes may be expected as a result of, for example, manufacturing techniques and/or tolerances. Thus, the embodiments of the disclosure should not be construed as being limited to the particular shapes of regions illustrated herein but may include deviations in shapes that result, for example, from manufacturing processes.

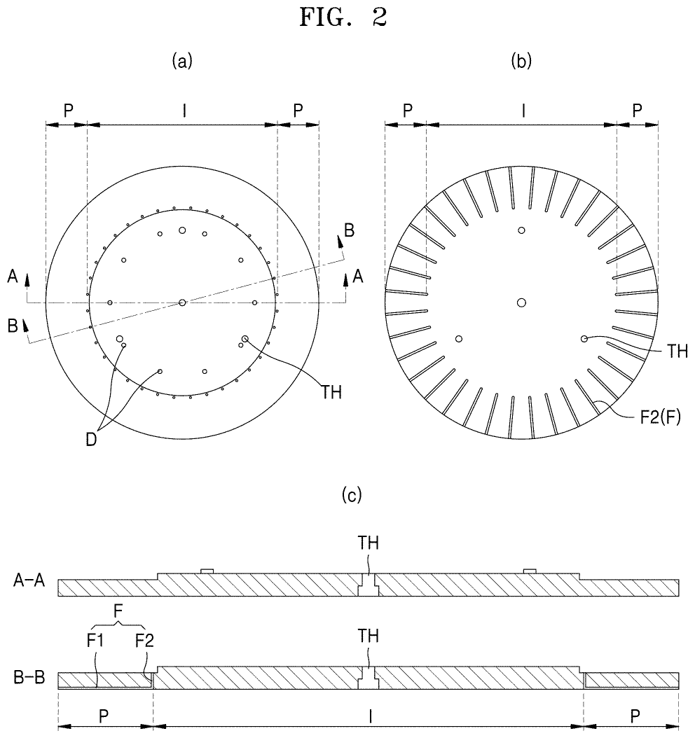

FIG. 2 is a view of a substrate support plate according to embodiments of the inventive concept. FIG. 2 (a) is a plan view of the substrate support plate, FIG. 2 (b) is a bottom view of the substrate support plate, and FIG. 2 (c) is a cross-sectional view of the substrate support plate taken along line A-A and line B-B.

Referring to FIG. 2, the substrate support plate is a configuration for supporting a substrate to be processed, and the substrate to be processed may be seated on the substrate support plate. The substrate support plate may include an inner portion I, a peripheral portion P, and at least one pad D. In addition, a path F and a through hole TH may be formed in the substrate support plate.

The inner portion I may be defined as a central region of the substrate support plate. The inner portion I may be formed to have an upper surface less than the area of the substrate to be processed. The upper surface of the inner portion I may have a shape corresponding to the shape of the substrate to be processed. For example, when the substrate to be processed is a circular substrate having a first diameter, the inner portion I may have a circular upper surface having a second diameter less than the first diameter.

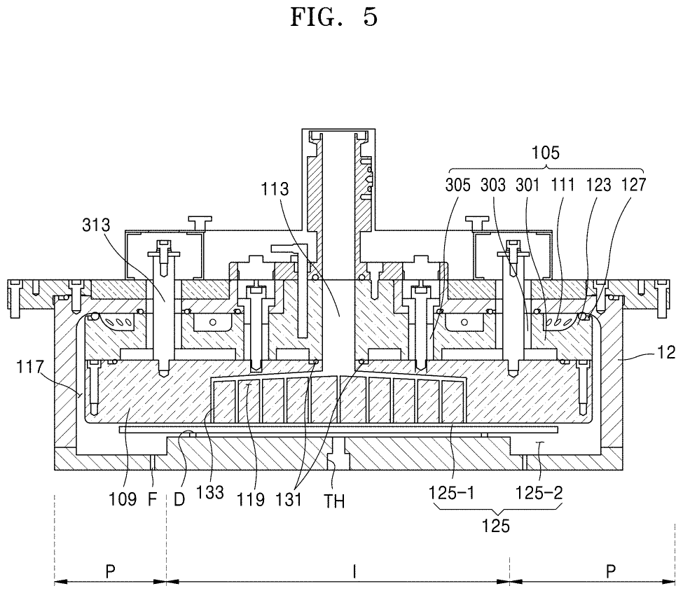

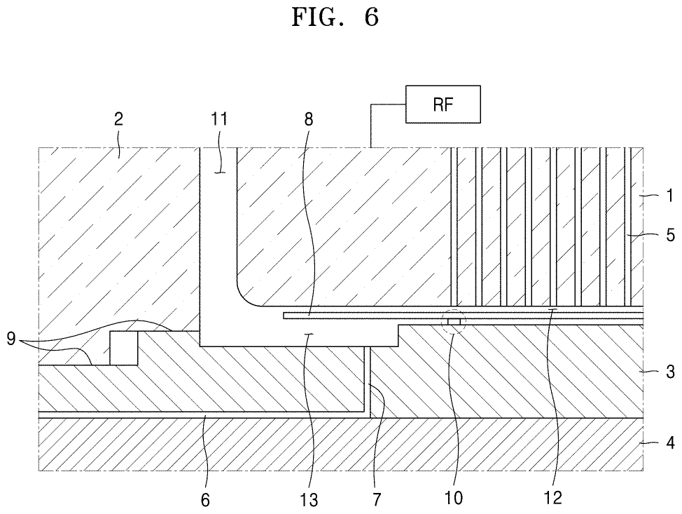

The peripheral portion P may be formed to surround the inner portion I. For example, when the inner portion I is a plate-like structure having a circular upper surface, the peripheral portion P may be a ring-shaped configuration that surrounds this plate-like structure. In an example, the peripheral portion P may be extended such that an upper surface of the peripheral portion P is disposed below the upper surface of the inner portion I. Therefore, a substrate support plate having a shape in which the inner portion I protrudes from the peripheral portion P may be formed. In an alternative embodiment, the inner portion I may form a convex portion of the substrate support plate, and the peripheral portion P may form a concave portion of the substrate support plate (see FIGS. 5 and 6).

At least one pad D may be on the inner portion I. For example, the at least one pad D may be plural, and the plurality of pads may be symmetrically formed with respect to the center of the substrate support plate. The substrate to be processed may be seated on the substrate support plate to be in contact with the at least one pad D. In an example, the at least one pad D may be configured to prevent horizontal movement of the substrate to be processed seated on the substrate support plate. For example, the at least one pad D may include a material having a certain roughness, and the roughness of the material may prevent slippage of the substrate to be processed.

The peripheral portion P may include at least one path F. In an example, as shown in FIG. 2, the path F may extend from a portion of the peripheral portion to another portion of the peripheral portion. In another example, the path F may extend from a portion of the peripheral portion toward a portion of the inner portion. As described above, the fact that the peripheral portion includes at least one path F means that at least one end of the path is formed at the peripheral portion.

In an example where the path F extends from one portion of the peripheral portion P to another portion of the peripheral portion P, the path F may be formed to penetrate the peripheral portion P. In an alternative example, the path F may include a first portion F1 extending from a side surface of the substrate support plate toward the peripheral portion P and a second portion F2 extending from the peripheral portion P toward the upper surface of the substrate support plate.

The path F may function as a moving path of gas. For example, a gas reactive with a thin film on the substrate to be processed may be supplied through the path F. The gas is supplied through the path F while the upper surface of the peripheral portion P is disposed below the upper surface of the inner portion I, whereby partial processing of a thin film on an edge region (e.g., bevel region) of the substrate to be processed seated on the substrate support plate may be achieved.

The path F may include a plurality of paths. In an example, the plurality of paths may be symmetrically formed with respect to the center of the substrate support plate. Also, the plurality of paths may extend to face a rear surface of the substrate to be processed. For example, a distance from the center of the substrate support plate to the path F of the peripheral portion P may be less than the radius of the substrate to be processed. Therefore, the gas may be uniformly supplied onto the rear surface of the substrate to be processed seated on the substrate support plate through the plurality of symmetrically formed paths.

The through hole TH may be formed in the inner portion I. The through hole TH formed in a peripheral portion of the inner portion I may provide a space in which a substrate support pin used to move the substrate when the substrate is mounted moves. In addition, a fixing pin (not shown) for fixing the position of the substrate support plate may be inserted into the through hole located at the center of the inner portion I. In this respect, the through hole TH is distinguished from the path F used as a moving path of the gas. For example, the through hole TH may be formed to have a diameter different from that of the path F.

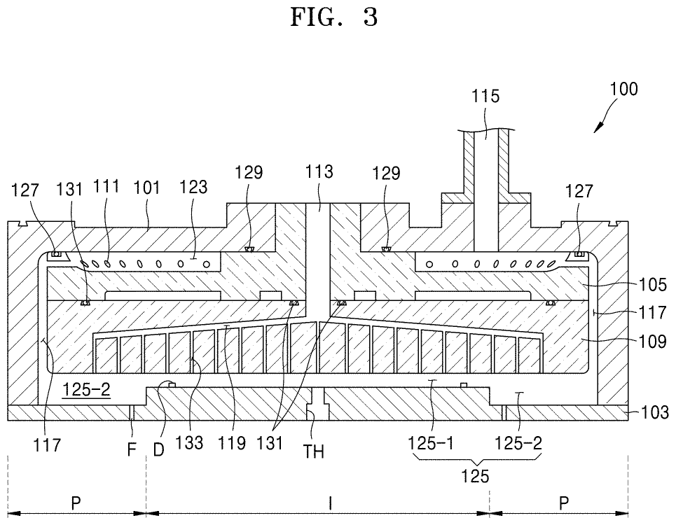

FIG. 3 is a view of a substrate processing apparatus according to embodiments of the inventive concept. The substrate processing apparatus according to these embodiments may include at least some of the features of a substrate support plate 103 according to the above-described embodiments. Hereinafter, repeated descriptions of the embodiments will not be given herein.

FIG. 3 shows a cross section of a semiconductor processing apparatus 100. The semiconductor processing apparatus 100 may include the substrate support plate 103 and a gas supply unit 109 on the substrate support plate 103.

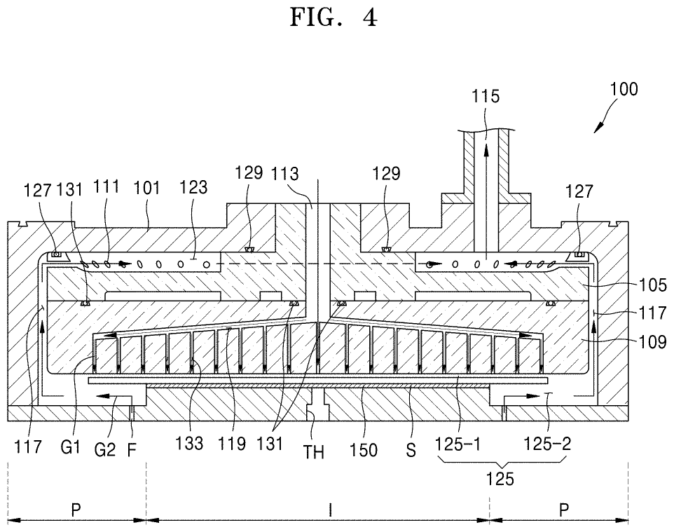

The gas supply unit 109 may include a plurality of injection holes. The plurality of injection holes may be formed to face an inner portion of the substrate support plate 103. In an example, the plurality of injection holes may be distributed over an area less than the area of the substrate to be processed (see FIGS. 3 and 4, etc.). In another example, the plurality of injection holes may be distributed over an area less than the area of an upper surface of the inner portion (see FIGS. 5 and 6, etc.). Such a distribution shape of the injection holes may contribute to facilitating partial processing of a thin film on an edge region of the substrate to be processed.

A first gas may be supplied through the plurality of injection holes of the gas supply unit 109. Meanwhile, as described above, a second gas different from the first gas may be supplied through the path F of the substrate support plate 103. The first gas may include an inert gas (e.g., argon) or a highly stable gas (e.g., nitrogen). The second gas may include a material reactive with the thin film on the substrate to be processed. For example, the second gas may include a gas (e.g., oxygen) used to oxidize the thin film.

As also mentioned above, the substrate support plate 103 may include at least some of the configurations of the substrate support plate according to the above-described embodiments. For example, the substrate support plate 103 may include the inner portion I having an upper surface of an area less than that of the substrate to be processed and the peripheral portion P surrounding the inner portion I. An upper surface of the peripheral portion P may also be disposed below the upper surface of the inner portion I.

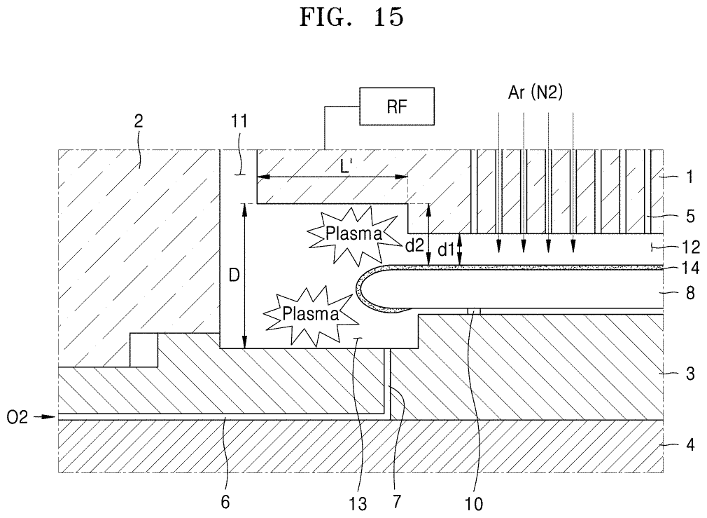

Since the inner portion I is located at a level higher than the peripheral portion P, a first distance between the inner portion I and the gas supply unit 109 may be less than a second distance between the peripheral portion P and the gas supply unit 109. That is, since a lower surface of the gas supply unit 109 is flat, a difference between the first distance and the second distance may occur. In an alternative embodiment, the lower surface of the gas supply unit 109 may not be flat (see FIG. 15), and even in this case, the first distance between the inner portion and the gas supply unit 109 may be less than the second distance between the peripheral portion and the gas supply unit 109.

According to some examples, when the substrate to be processed is mounted on the inner portion I, a distance between the substrate to be processed and the gas supply unit 109 may be about 1 mm or less, and the second distance between the peripheral portion P and the gas supply unit 109 may be about 3 mm or more. As such, by forming a sufficient distance between the peripheral portion P and the gas supply unit 109, partial processing of the thin film on the edge region of the substrate to be processed seated on the substrate support plate 103 may be achieved.

Among the above-described embodiments, when the lower surface of the gas supply unit 109 is flat and a difference between the first distance and the second distance is realized, further technical advantages may be achieved. In more detail, when a first lower surface of the gas supply unit 109 in a region where the plurality of injection holes are distributed is flush with a second lower surface of the gas supply unit 109 outside the region where the plurality of injection holes are distributed (see FIG. 4), the distance between the substrate to be processed and the gas supply unit 109 may be constant.

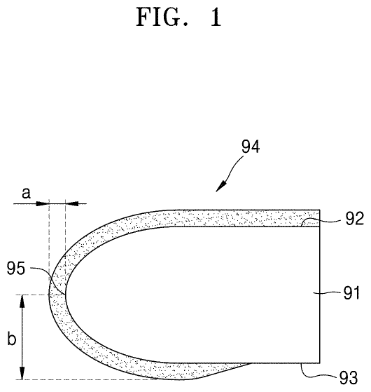

In this case, a distance between the upper surface of the substrate to be processed and the first lower surface and a distance between the upper surface of the substrate to be processed and the second lower surface are constant. As a result, processing of the thin film (see a and b of FIG. 1) on the edge region of the substrate to be processed disposed between the peripheral portion P and the gas supply unit 109 may be performed without a separate alignment operation. For example, by adjusting a flow rate ratio of the first gas supplied through the gas supply unit 109 to the second gas supplied through the at least one path F, removal of the thin film on the edge region with respect to the substrate to be processed in an unaligned state may be performed.

Meanwhile, when the second lower surface outside the injection hole is disposed at a level different from the level of the first lower surface around the injection hole (see, e.g., FIG. 15), the degree of processing (e.g., removal) of the thin film on the edge region of the substrate to be processed may be affected by the distance between the thin film and the lower surface. Thus, in such a case, an alignment form of the substrate to be processed on the substrate support plate 103 will affect symmetry of the processing of the thin film on the edge region.

Referring again to FIG. 3, in the semiconductor processing apparatus 100, a reactor wall 101 may be in contact with the substrate support plate 103. In more detail, the reaction space 125 may be formed between the substrate support plate 103 and the gas supply unit 109 while a lower surface of the reactor wall 101 is in contact with the substrate support plate 103 serving as a lower electrode. The reaction space 125 may include a first reaction space 125-1 between the inner portion and the gas supply unit 109 and a second reaction space 125-2 between the peripheral portion and the gas supply unit 109.

In some embodiments, the first reaction space 125-1 may be configured to process a thin film on a central region of the substrate to be processed. The second reaction space 125-2 may be configured to process a thin film on the edge region of the substrate to be processed. For example, in order to process the thin film on the substrate, power may be supplied between the gas supply unit 109 and the substrate support plate 103, and plasma may be generate in the second reaction space 125-2 by the power supply. In some additional examples, plasma may be generated in the first reaction space 125-1 and the second reaction space 125-2 by the power supply.

As described above, since a distance between the substrate support plate 103 and the gas supply unit 109 in the first reaction space 125-1 is less than the distance between the substrate support plate 103 and the gas supply unit 109 in the second reaction space 125-2, less plasma may be formed in the first reaction space 125-1 with a less distance by Paschen's law. In other words, the plasma of the first reaction space 125-1 may be less than the plasma of the second reaction space 125-2. In the present specification, it should be noted that the plasma in the first reaction space is less than the plasma in the second reaction space includes a case where plasma is formed in the second reaction space and no plasma is formed in the first reaction space.

The substrate support plate 103 may be configured to face seal with the reactor wall 101. The reaction space 125 may be formed between the reactor wall 101 and the substrate support plate 103 by the face sealing. In addition, a gas exhaust path 117 may be formed between a gas flow control device 105 and the gas supply unit 109 and the reactor wall by the face sealing.

The gas flow control device 105 and the gas supply unit 109 may be disposed between the reactor wall 101 and the substrate support plate 103. The gas flow control device 105 and the gas supply unit 109 may be integrally formed, or may be configured in a separate type in which portions having injection holes 133 are separated. In the separate structure, the gas flow control device 105 may be stacked on the gas supply unit 109. Optionally, the gas supply unit 109 may also be configured separately, in which case the gas supply unit 109 may include a gas injection device having a plurality of through holes and a gas channel stacked on the gas injection device.

The gas flow control device 105 may include a plate and a sidewall 123 protruding from the plate. A plurality of holes 111 penetrating the side wall 123 may be formed in the side wall 123.

Grooves 127, 129, and 317 for accommodating a sealing member such as an 0-ring may be formed between the reactor wall 101 and the gas flow control device 105 and between the gas flow control device 105 and the gas supply unit 109. By the sealing member, an external gas may be prevented from entering the reaction space 125. In addition, by the sealing member, a reaction gas in the reaction space 125 may exit along a defined path (i.e., the gas exhaust path 117 and a gas outlet 115, see FIG. 4). Therefore, the outflow of the reaction gas into a region other than the defined path may be prevented.

The gas supply unit 109 may be used as an electrode in a plasma process such as a capacitively coupled plasma (CCP) method. In this case, the gas supply unit 109 may include a metal material such as aluminum (Al). In the CCP method, the substrate support plate 103 may also be used as an electrode, so that capacitive coupling may be achieved by the gas supply unit 109 serving as a first electrode and the substrate support plate 103 serving as a second electrode.

In more detail, plasma generated in an external plasma generator (not shown) may be transmitted to the gas supply unit 109 by an RF rod 313 (of FIG. 5). The RF rod may be mechanically connected to the gas supply unit 109 through an RF rod hole 303 (of FIG. 5) penetrating an upper portion of the reactor wall 101 and the gas flow control device 105.

Optionally, the gas supply unit 109 is formed of a conductor while the gas flow control device 105 includes an insulating material such as ceramics so that the gas supply unit 109 used as a plasma electrode may be insulated from the reactor wall 101.

As shown in FIG. 3, a gas inlet 113, which penetrates the reactor wall 101 and the central portion of the gas flow control device 105, is formed in an upper portion of the reactor wall 101. In addition, a gas flow path 119 is further formed in the gas supply unit 109, and thus a reaction gas supplied through the gas inlet 113 from an external gas supply unit (not shown) may be uniformly supplied to each of the injection holes 133 of the gas supply unit 109.

In addition, as shown in FIG. 3, the gas outlet 115 is disposed at the top of the reactor wall 101 and asymmetrically with respect to the gas inlet 113. Although not shown in the drawings, the gas outlet 115 may be disposed symmetrically with respect to the gas inlet 113. In addition, the reactor wall 101 and a sidewall of the gas flow control device 105 (and a sidewall of the gas supply unit 109) are apart from each other, and thus the gas exhaust path 117 through which a residual gas of the reaction gas is exhausted may be formed after the process proceeds.

The thin film on the edge region of the substrate to be processed may be removed through the substrate processing apparatus described above, and operations for removing the thin film may be performed as follows.
First operation: a substrate to be processed is mounted on the substrate support plate 103. For example, the substrate support plate 103 descends and a substrate support pin ascends through a through hole. The substrate to be processed is then transmitted from a robot arm onto the substrate support pin. The substrate support pin then descends and the substrate to be processed is seated onto the inner portion of the substrate support plate 103. Thereafter, the substrate support plate 103 ascends to form the first reaction space 125-1 and the second reaction space 125-2.
Second operation: Power is supplied between the gas supply unit 109 on the substrate support plate 103 and the substrate support plate 103 to generate plasma. For example, a second gas is supplied to the reaction space 125 through the path F, and then the second gas is ionized by a potential difference formed between the gas supply unit 109 and the substrate support plate 103 to generate a radical. The radical may be reactive with a thin film of the substrate to be processed.

Meanwhile, an upper surface of the inner portion of the substrate support plate 103 may be located above the upper surface of the peripheral portion. Therefore, a first distance between the inner portion and the gas supply unit 109 may be less than a second distance between the peripheral portion and the gas supply unit 109. As a result, while the number of radicals generated in the first reaction space 125-1 with a less distance between the inner portion of the substrate support plate 103 and the gas supply unit 109 is relatively small or absent, the number of radicals generated in the second reaction space 125-2 with a large distance between the peripheral portion of the substrate support plate 103 and the gas supply unit 109 will be relatively large.
Third operation: The generated plasma is used to remove at least a portion of the thin film on the edge region of the substrate to be processed. For example, the thin film may be removed by reacting with the radical generated in the second operation. As described above, since radicals are relatively formed a lot in a peripheral portion of the substrate support plate 103, most of the thin film may be removed in the edge region of the substrate to be processed.

FIG. 4 schematically shows a substrate processing apparatus according to embodiments of the inventive concept. The substrate processing apparatus according to the embodiments may be a variation of the substrate processing apparatus according to the above-described embodiments. Hereinafter, repeated descriptions of the embodiments will not be given herein.

Referring to FIG. 4, a first gas G1 and a second gas G2 may be supplied to the reaction space 125 of the semiconductor processing apparatus. The second gas G2 may include a component reactive with a thin film on a substrate S to be processed. The second gas G2 may be supplied through the path F of the substrate support plate 103. In addition, the second substrate G2 may be supplied toward a rear surface of the substrate S to be processed, and the second substrate G2 may be supplied toward the edge region of the substrate S to be processed.

The first gas G1 may include a component different from the second gas G2. For example, the first gas G1 may include a component that is not reactive with a thin film on the substrate S to be processed. The first gas G1 may be supplied through an injection hole 133 of the gas supply unit 109. In addition, the first gas G1 may be supplied toward an upper surface of the substrate S to be processed (i.e., the surface on which the thin film is formed). For example, the first gas G1 may be supplied toward a central region of the substrate S to be processed. In another example, the first gas G1 may be uniformly supplied over the entire area of the substrate S to be processed.

As described above, the reaction space 125 may include the first reaction space 125-1 and the second reaction space 125-2. When power is applied, a relatively small amount of plasma is generated or no plasma is generated in the first reaction space 125-1 between the inner portion I and the gas supply unit 109. However, a relatively large amount of plasma may be generated in the second reaction space 125-2 between the peripheral portion P and the gas supply units 109.

Therefore, in the second reaction space 125-2 in which a relatively large amount of plasma is generated, a reaction between the thin film on the substrate S to be processed and the second gas G2 may be promoted. As a result, a chemical reaction on the edge region of the substrate S to be processed may be performed, and the thin film on the edge region of the substrate S to be processed may be removed.

A residual gas after removing the thin film on the edge region is transmitted to the gas flow control device 105 through the gas exhaust path 117 formed between the reactor wall 101 and a side wall of the gas supply unit 109. The gas transmitted to the gas flow control device 105 may be introduced into an internal space of the gas flow control device 105 through the through holes 111 formed in the side wall 123 and then exhausted to the outside through the gas outlet 115.

In an alternative embodiment, at least a portion of the inner portion I of the substrate support plate 103 may be anodized. By the anodizing, an insulating layer 150 may be formed on at least a portion of the upper surface of the inner portion I. For example, the insulating layer 150 may include aluminum oxide. By an anodizing process, adhesion of a substrate may be achieved by electrostatic force. Unloading of the adhered substrate may be performed more easily.

FIG. 5 is a cross-sectional view of a semiconductor processing apparatus according to the disclosure seen from another cross section. Referring to FIG. 5, the gas flow control device 105 includes a side wall 123, a gas inlet 113, a plate 301 surrounded by the side wall 123, an RF rod hole 303, a screw hole 305, a through hole 111, and a groove 127 for receiving a sealing member such as an O-ring.

The plate 301 may be surrounded by the protruding sidewall 123 and may have a concave shape. A portion of the gas flow control device 105 is disposed with the gas inlet 113, which is a path through which an external reaction gas is introduced. At least two screw holes 305 are provided around the gas inlet 113, and a screw, which is a mechanical connecting member connecting the gas flow control device 105 to the gas supply unit 109, passes through the screw hole 305. The other portion of the gas flow control device 105 is provided with the RF rod hole 303, and thus the RF rod 313 connected to an external plasma supply unit (not shown) may be mechanically connected to the gas supply unit 109 below the gas flow control device 105.

The gas supply unit 109 connected to the RF rod 313 may serve as an electrode in a CCP process. In this case, a gas supplied by a gas channel and a gas injection device of the gas supply unit 109 will be activated in a reaction space by the gas supply unit 109 serving as an electrode and injected onto a substrate on the substrate support plate 103.

In some embodiments, the injection hole 133 of the gas supply unit 109 may be distributed over an area less than the area of the substrate S to be processed. In a further embodiment, the injection holes 133 of the gas supply unit 109 may be distributed over an area less than the area of the upper surface of the inner portion I of the substrate support plate. By arranging the injection holes 133 as described above, a more intensive process for the edge region of the substrate S to be processed may be achieved. That is, by reducing the area of a supply region of a first gas supplied through the injection hole 133, the amount of dilution of a second gas supplied toward the rear surface of the substrate S to be processed through the path F by the first gas supplied toward an upper surface of the substrate S to be processed may be reduced.

In some embodiments, the inner portion I of the substrate support plate 103 may protrude from the peripheral portion P of the substrate support plate 103, and thus the inner portion I may form a convex portion of the substrate support plate 103. Also, in some embodiments, the peripheral portion P of the substrate support plate 103 may form a concave portion of the substrate support plate 103. That is, a portion of the substrate support plate 103 face sealing with the reactor wall 101 protrudes from an upper surface of the peripheral portion P, thereby forming a concave portion in the peripheral portion P of the substrate support plate 103.

FIG. 6 is a view of a substrate processing apparatus according to embodiments of the inventive concept. The substrate processing apparatus according to the embodiments may be a variation of the substrate processing apparatus according to the above-described embodiments. Hereinafter, repeated descriptions of the embodiments will not be given herein.

Referring to FIG. 6, a susceptor 3 is provided on a heating block 4 and a substrate 8 is loaded on the susceptor 3. The susceptor 3 may include a concave portion and a convex portion. The concave portion may be formed in a peripheral portion of the susceptor 3, and the convex portion may be formed in an inner portion of the susceptor 3. The substrate 8 may be seated on the inner portion, and the inner portion of the susceptor may support the substrate 8.

A lower surface of a reactor wall 2 and the susceptor 3 may face seal at a step 9, and reaction spaces 12 and 13 may be formed by the face sealing. The reaction space may include a first reaction space 12 and a second reaction space 13. The first reaction space 12 may be formed between the inner portion of the susceptor 3 and a gas supply unit 1. The second reaction space 13 may be formed between the peripheral portion of the susceptor 3, that is, the edge of a rear surface of the substrate 8 and a concave portion of the susceptor 3.

A first gas is supplied to a first reaction space 12 on the substrate through a first gas inlet 5 of the gas supply unit 1, and a second gas is supplied to the second reaction space 13 below an edge of the substrate through a second gas inlet 6 and a third gas inlet 7 formed in the susceptor 3. The second gas may include oxygen. For example, by filling the inside of an external chamber (not shown) on which the reactor is mounted with oxygen, oxygen gas may be introduced into the reaction space as a filling gas.

The second gas inlet 6 may be formed in a horizontal direction between a lower portion of the susceptor 3 and the heating block 4, and the third gas inlet 7 may be formed by vertically penetrating the susceptor at a position corresponding to the second reaction space below the edge of the substrate. The second gas inlet 6 and the third gas inlet 7 may communicate with each other.

A gas in the reaction space is exhausted through an exhaust portion 11, and an upper exhaust system is illustrated in FIG. 6. However, it is noted that the exhaust system is not limited thereto, and a lower exhaust system, a side exhaust system, or a combination thereof may also be applied.

The edge of the substrate, that is, a bevel region, is not supported by the susceptor 3 and is exposed on the concave portion of the susceptor 3, that is, the second reaction space 13. The gas supply unit 1 is connected to an RF generator, and when RF power is supplied to the gas supply unit 1, plasma is generated in the second reaction space 13.

The gas supply unit 1 has a plurality of through holes 5 therein, and the first gas may be supplied to the first reaction space 12 through the through holes 5. The gas supply unit 1 may be, for example, a showerhead, and may be made of a metal material to function as an RF electrode. The first gas supplied to the first gas inlet 5 may be nitrogen or argon. The second gas supplied to the second gas inlet 6 and the third gas inlet 7 may be oxygen.

The substrate 8 is loaded onto a pad 10 on the convex portion of the susceptor 3. According to the prior art, the susceptor has a concave pocket structure to prevent sliding when loading the substrate and allows the substrate to be seated into the pocket of the susceptor. However, in the disclosure, for etching of the edge of the substrate, the susceptor may have a structure opposite to the pocket structure. That is, an edge portion of the susceptor has a stepped structure, and thus a rear surface of the edge portion of the substrate is not supported and is exposed to the second reaction space.

The pad 10 is introduced to prevent the substrate 8 from sliding by a gas pocket between the rear surface of the substrate and the susceptor when the substrate 8 is loaded onto the susceptor 3. That is, by introducing the pad 10, when the substrate 8 is seated on the susceptor 3, the substrate 8 may be prevented from sliding by a gas between the rear surface of the substrate and the susceptor.

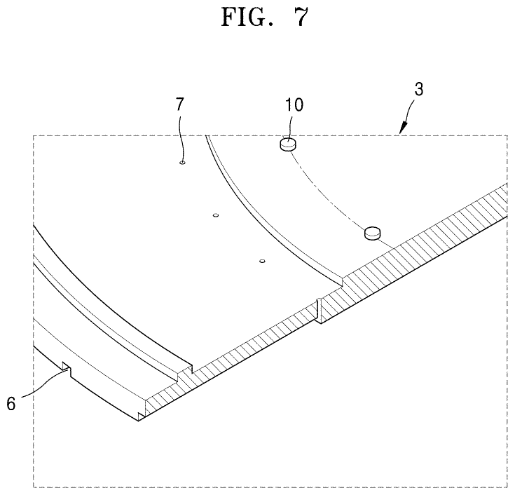

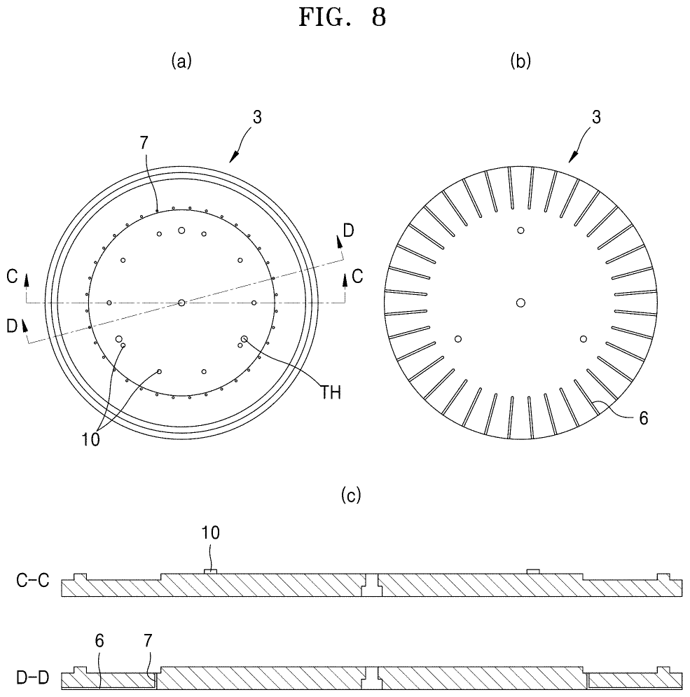

FIGS. 7 and 8 are views of a substrate support plate according to embodiments of the inventive concept. The substrate support plate according to the embodiments may be a modification of the substrate support plate according to the above-described embodiments and the substrate support plate included in the substrate processing apparatus. Hereinafter, repeated descriptions of the embodiments will not be given herein.

Referring to FIG. 7, the second gas inlet 6 may be a concave portion formed in a horizontal direction in a straight line on a rear surface of a susceptor. The second gas inlet 6 may form a gas path through which a second gas is supplied together with an upper surface of a heating block (not shown) supporting the susceptor 3. In another example, the second gas inlet 6 may be formed directly through the side of the susceptor 3.

The third gas inlet 7 may vertically penetrate the concave portion of the susceptor 3 and communicate with the second gas inlet 6 within the body of the susceptor 3. The second gas may be supplied to the concave portion of the susceptor 3 through the second gas inlet 6 and the third gas inlet 7. The second gas inlet 6 and the third gas inlet 7 may be provided in plurality on the susceptor while maintaining a certain interval with respect to the center of the susceptor. For example, 36 second and third gas inlets may be provided on the susceptor at 10 degree intervals. Through the plurality of second gas inlets 6 and the third gas inlets 7, a uniform amount of second gas may be supplied to the concave portion.

The pad 10 may be provided at an inner portion of the susceptor 3. The pad 10 may support a substrate. As described above, since the substrate is loaded on the pad 10, separation or sliding of the substrate due to a gas between a rear surface of the substrate and an upper surface of the susceptor 3 may be prevented. The pad 10 may be provided in plurality at regular intervals based on the center of the susceptor. For example, according to some embodiments, 10 pads 10 may be provided at 36 degree intervals. In some examples, the thickness of the pad 10 may be about 0.5 mm.

The structure of the susceptor 3 is shown in more detail in FIG. 8. FIG. 8 (a) shows an upper surface of the susceptor and FIG. 8 (c) are cross-sectional views taken along lines C-C and D-D of FIG. 8 (a). The cross-section along line D-D shows that a second gas inlet and a third gas inlet are formed in the bodt of the susceptor. FIG. 8 (b) shows a lower surface of the susceptor and shows a plurality of concave portions, that is, second gas inlets formed at regular intervals from the edge of the susceptor towards the center at the lower surface.

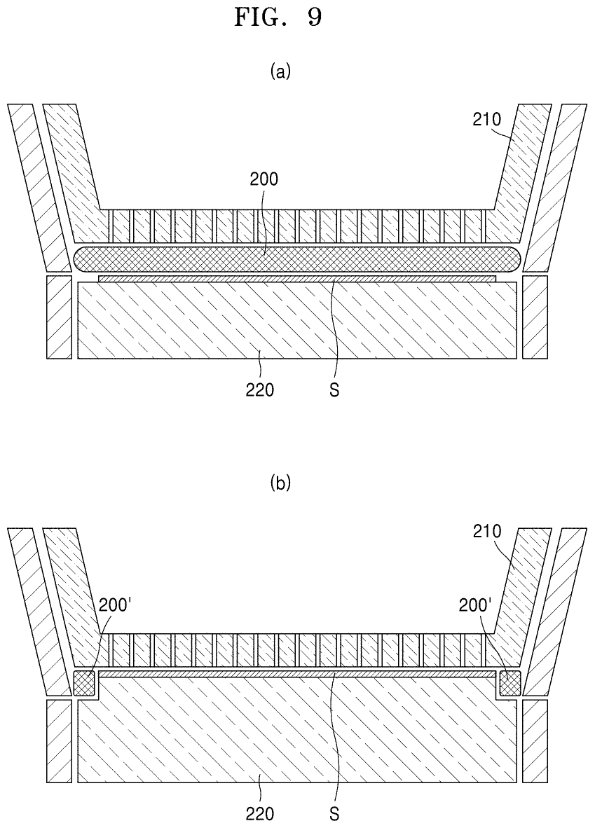

FIG. 9 schematically shows a substrate processing device according to embodiments. The substrate processing apparatus according to the embodiments may be a variation of the substrate processing apparatus according to the above-described embodiments. Hereinafter, repeated descriptions of the embodiments will not be given herein.

Referring to FIG. 9, next, selective etching may be performed in an edge region of a substrate, specifically, a bevel region.

As shown in FIG. 9, different plasma generation regions are implemented according to a reactor structure. FIG. 9 (a) shows that plasma 200 is generated over the entire reaction space on the substrate. However, FIG. 9 (b) shows that plasma 200′ is generated only the edge region of the substrate, specifically, the bevel region. This difference may occur due to a distance between the substrate and an electrode, specifically, a distance between the susceptor and an upper electrode (e.g., the gas supply unit 210).

According to Paschen's law, plasma generation is determined by pressure and distance in the reaction space. That is, when the pressure in the reaction space is constant, in the short distance reaction space, a mean free path of gas molecules is short, so the probability of collision between gas molecules is low and ionization is difficult. In addition, since the acceleration distance is short, the discharge is difficult, and thus plasma is hardly generated. In general, when the distance of the reaction space is less than 1 mm, plasma generation is difficult.

In FIG. 9 (a), the distance of a reaction space between the substrate S and the electrode 210 may be 1 mm or more. In this case, when gas is supplied to the reaction space through the gas supply unit (i.e. shower head electrode 210) and RF power is supplied, the plasma 200 may be generated in the reaction space on the substrate.

In FIG. 9 (b), the distance of the reaction space on the substrate S, that is, a first reaction space from an inner portion of the susceptor may be 1 mm or less, and as a result, plasma generation in the first reaction space is difficult even when the gas and the RF electrode are supplied. However, in a second reaction space having the bevel region, which is the edge region of the substrate, since the susceptor is a concave, the distance between electrodes 210 and 220 may be 1 mm or more, so that the plasma 200′ may be generated in the second reaction space. Therefore, this reactor structure allows etching and deposition in the bevel region of the substrate.

Embodiments according to the inventive concept use this principle, and by introducing a concave structure such that the distance of a reaction space from the inner portion of the susceptor, for example, the distance between a substrate and an electrode is within about 1 mm, and the distance of the reaction space from a bevel region of the substrate, that is, a peripheral portion of the susceptor, is 1 mm or more, plasma generation may be easily achieved in the bevel region of the substrate.

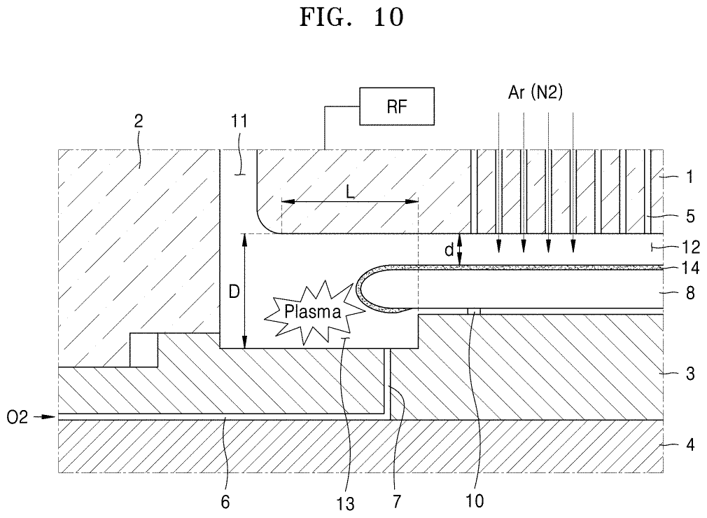

FIG. 10 is a view of a substrate processing apparatus according to embodiments of the inventive concept. The substrate processing apparatus according to the embodiments may be a variation of the substrate processing apparatus according to the above-described embodiments. Hereinafter, repeated descriptions of the embodiments will not be given herein.

Referring to FIG. 10, in a bevel region of a substrate, a film deposited on the substrate may be removed. For example, a carbon film may be deposited on the substrate 8. Argon or nitrogen, which is a first gas, may be supplied to the first reaction space 12 through the first gas inlet 5 of the gas supply unit 1. Oxygen gas, which is a second gas, may be supplied to the second reaction space 13 through the second gas inlet 6 and the third gas inlet 7 of the susceptor 3.

According to an example, a first distance d of the first reaction space 12 may be 1 mm or less. In addition, a second distance D of the second reaction space 13 may be 3 mm or more. When RF power is supplied to the gas supply unit 1, plasma is not generated in the first reaction space 12 due to the short first distance d, but plasma may be generated in the second reaction space 13. In particular, as oxygen supplied through the second and third gas inlets ionizes, oxygen plasma may be generated. In this case, an oxygen radical and a carbon thin film of the bevel region of the substrate may react to remove the carbon thin film of the bevel region of the substrate.

According to one of the technical features of the disclosure, a bevel etching region having the same width may be secured on the substrate wherever the substrate is located within a length L of the second reaction space L. That is, irrespective of the alignment position of the substrate 8 on the susceptor 3, symmetrical bevel etching of the same width is possible on the substrate.

In more detail, as long as an edge region of the substrate is in the region of the length L of the second reaction space, the symmetric bevel etching may be achieved by adjusting the magnitude of RF power or a flow rate ratio of a first gas and a second gas flowing therein. Since a lower surface of a gas supply unit 1, that is, a surface facing the substrate is flat without bending, and the first distance d between an upper surface of the substrate 8 and a lower surface of a gas supply unit 10 is constant, no plasma is generated on an upper surface of the substrate, and symmetrical bevel etching may be achieved with respect to side and lower surfaces of the substrate by adjusting the magnitude of RF power and the flow rate ratio of gas.

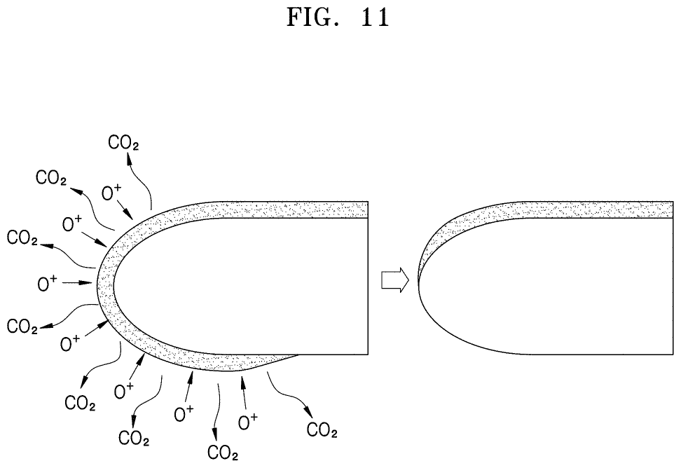

FIG. 11 shows that a carbon thin film is removed through a reaction of an oxygen radical and a carbon thin film. In FIG. 11, a carbon component of the carbon thin film may be converted into a CO2 gas by reacting with the oxygen radical and removed. As shown in FIG. 11, it can be seen that a thin film of a bevel region of a substrate is selectively removed by implementing reaction spaces having different widths. According to a further embodiment, as described above, the region where the thin film is removed of the bevel region of the substrate may be controlled according to conditions of applied RF power, and thus the selective removal of the thin film of the bevel region of the substrate may be achieved without an alignment operation of the substrate.

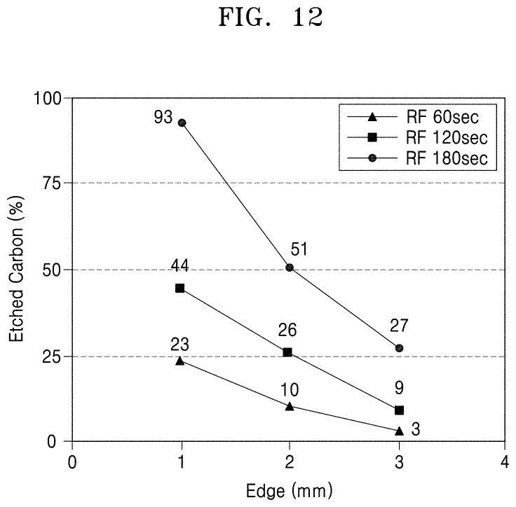

FIG. 12 shows a region where a carbon thin film is removed from an upper edge of a substrate according to an RF power application time. The experiment results in FIG. 12 are obtained under conditions of a heating block of 300° C., RF power of 800 watts, 500 sccm of Ar (first gas), 1500 sccm of O2 (second gas), and pressure of 3 Torr in a reactor.

As shown in FIG. 12, in the present experiment, it can be seen that 23% of the carbon thin film was removed at an inner portion of the substrate 1 mm away from an edge of the substrate, 10% of the carbon thin film was removed at a portion 2 mm away from the edge of the substrate, and 3% of the carbon thin film was removed at a portion 3 mm away from the edge of the substrate when RF power was applied for 60 seconds.

Also, in the present experiment, it can be seen that 44% of the carbon thin film was removed at an inner portion of the substrate 1 mm away from the edge of the substrate, 26% of the carbon thin film was removed at the 2 mm away portion, and 9% of the carbon thin film was removed at the 3 mm away portion when RF power was applied for 120 seconds.

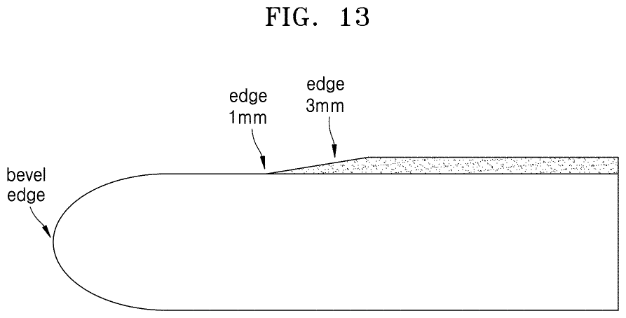

In addition, in the present experiment, it can be seen that 93% of the carbon thin film was removed at an inner portion of the substrate 1 mm away from the edge of the substrate, 51% of the carbon thin film was removed at a portion 2 mm away from the edge of the substrate, and 27% of the carbon thin film was removed at a portion 3 mm away from the edge of the substrate when RF power was applied for 180 seconds. The removal of the carbon thin film by position is shown in more detail in FIG. 13.

In FIGS. 12 to 13, oxygen gas is supplied to remove the carbon thin film, but the inventive concept is not limited thereto. For example, SiO₂, SiN, Poly-Si, and metal thin films may be deposited on a substrate, in which case as a second gas including a material reactive with the thin film, a gas including F, for example, an etching gas such as F₂, NF₃, CIF₃ and Cl₂ may be used.

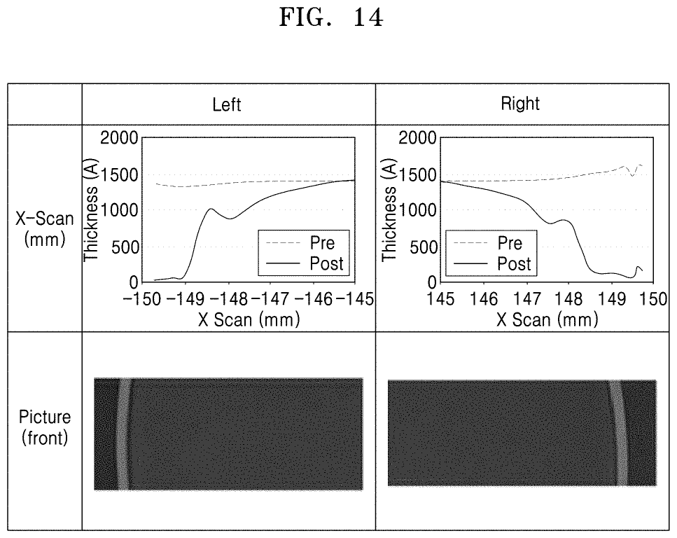

FIG. 14 shows that a carbon thin film is removed from the edge 1 mm of an upper surface of an actual substrate, which is proceeded under a condition of applying RF power for 180 seconds under the above-described process conditions of FIG. 12.

As shown in FIG. 14, 90% or more of the carbon thin film is removed at the edge 1 mm of the substrate, and the amount of the thin film removed is gradually decreased toward the inner portion of the substrate.

The RF power application time is controlled in FIGS. 12 to 14, but the same effect may be achieved by controlling a pressure ratio between a first reaction space and a second reaction space. That is, by controlling a supply ratio of the first gas and the second gas, selective thin film removal in the bevel region may be implemented.

For example, in FIGS. 12 to 14, Ar, which is the first gas, and O2, which is the second gas, are supplied at a ratio of 1:3 (i.e., 500 sccm:1500 sccm). However, in an alternative embodiment, a supply flow rate of the first gas may be reduced to extend a supply region of oxygen radicals at the edge of the upper surface of the substrate, and in this case, the region where the carbon thin film is removed may be enlarged.

In addition, according to other embodiments, the same effect may be achieved by changing a reactor structure (see FIG. 15). Referring to FIG. 15 schematically illustrating a substrate processing apparatus according to embodiments of the inventive concept, a step is introduced at an edge portion of the gas supply unit 1 to enlarge a reaction space distance d2 of a corresponding region. As the reaction space distance d2 is enlarged, a larger amount of plasma may be generated and the region where the thin film is removed in an upper edge portion of a substrate may be controlled.

In the embodiment of FIG. 15, the width of a bevel etching region at the edge of the substrate is determined according to a width of a step region L′ formed at the edge of the gas supply unit 1. Thus, unlike FIG. 10, the alignment of the substrate on the susceptor 4 will be an important process variable for the symmetry of a bevel etching width. That is, when plasma is generated at the edge of the substrate by providing a stepped structure at the edge of the gas supply unit to perform a bevel etching function, since a distance between a lower surface of the gas supply unit and an upper surface of the substrate is not constant (e.g., d1*d2), the alignment of the substrate on the susceptor is important to ensure a constant etching width.

As described above with reference to FIGS. 12 to 14, by adjusting the magnitude of RF power supplied to a reaction space and a flow rate ratio between incoming gases irrespective of the alignment of the substrate on the susceptor, a bevel removal region having a uniform width may be obtained at the edge of the substrate.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of the disclosure as defined by the following claims.

What is claimed is:

1. A substrate support plate for supporting a substrate to be processed, the substrate support plate comprising:
an inner portion having an upper surface having an area less than that of the substrate to be processed; and
a peripheral portion surrounding the inner portion,
wherein an upper surface of the peripheral portion is below the upper surface of the inner portion, and
the peripheral portion comprises at least one path.

2. The substrate support plate of claim 1,
further comprising: at least one pad disposed on the inner portion.

3. The substrate support plate of claim 1,
wherein the path extends from a portion of the peripheral portion to another portion of the peripheral portion.

4. The substrate support plate of claim 3,
wherein the path comprises:
a first portion extending from a side surface of the substrate support plate toward the peripheral portion; and
a second portion extending from the peripheral portion toward an upper surface of the substrate support plate.

5. The substrate support plate of claim 1,
wherein the path comprises a plurality of paths, and
the plurality of paths are symmetrically formed with respect to the center of the substrate support plate.

6. The substrate support plate of claim 5,
wherein the inner portion comprises a through hole having a diameter different from that of the path.

7. The substrate support plate of claim 1,
wherein a distance from the center of the substrate support plate to the path is less than the radius of the substrate to be processed.

8. A substrate processing apparatus comprising:
a substrate support plate comprising an inner portion having an upper surface of an area less than that of a substrate to be processed and a peripheral portion surrounding the inner portion, wherein an upper surface of the peripheral portion is below an upper surface of the inner portion; and
a gas supply unit on the substrate support plate,
wherein a first distance between the inner portion and the gas supply unit is less than a second distance between the peripheral portion and the gas supply unit.

9. The substrate processing apparatus of claim 8,
wherein, when the substrate to be processed is mounted on the inner portion, a distance between the substrate to be processed and the gas supply unit is about 1 mm or less, and
a second distance between the peripheral portion and the gas supply unit is about 3 mm or more.

10. The substrate processing apparatus of claim 8,
wherein the inner portion forms a convex portion of the substrate support plate, and the peripheral portion forms a concave portion of the substrate support plate.

11. The substrate processing apparatus of claim 8,
wherein the gas supply unit comprises a plurality of injection holes distributed over an area less than that of the substrate to be processed.

12. The substrate processing apparatus of claim 11,
wherein the plurality of injection holes are distributed over an area less than that of the upper surface of the inner portion.

13. The substrate processing apparatus of claim 8,
wherein the gas supply unit comprises a plurality of injection holes, and
a first lower surface of the gas supply unit in a region where the plurality of injection holes are distributed is flush with a second lower surface of the gas supply unit outside the region where the plurality of injection holes are distributed.

14. The substrate processing apparatus of claim 13,
wherein a distance between an upper surface of the substrate to be processed and the first lower surface of the gas supply unit and a distance between the upper surface of the substrate to be processed and the second lower surface of the gas supply unit are constant, and accordingly, processing of a thin film on an edge region of the substrate to be processed disposed between the peripheral portion and the gas supply unit is performed without a separate alignment operation.

15. The substrate processing apparatus of claim 8,
wherein a reaction space is formed between the substrate support plate and the gas supply unit, and
the reaction space comprises:
a first reaction space between the inner portion and the gas supply unit; and
a second reaction space between the peripheral portion and the gas supply unit.

16. The substrate processing apparatus of claim 15,
wherein power is supplied between the gas supply unit and the substrate support plate to generate plasma, and
less plasma is generated in the first reaction space than plasma in the second reaction space.

17. The substrate processing apparatus of claim 8,
the peripheral portion comprises at least one path.

18. The substrate processing apparatus of claim 17,
wherein the substrate processing apparatus is configured to supply, through the path, a gas reactive with the thin film on the substrate to be processed.

19. The substrate processing apparatus of claim 18,
wherein the substrate processing apparatus is configured to supply, through the gas supply unit, a gas different from the gas reactive with the thin film.

20. A substrate processing method comprising:
mounting a substrate to be processed on the substrate support plate of the substrate processing apparatus of claim 8;
generating plasma by supplying power between a gas supply unit on the substrate support plate and the substrate support plate; and
removing at least a portion of a thin film on an edge region of the substrate to be processed using the plasma,
wherein, during the generating of the plasma, less plasma is generated in a first space between the inner portion and the gas supply unit than in a second space between the peripheral portion and the gas supply unit.
